(19) United States
(12) Patent Application Publication
(10) Pub. No.: US 2015/0163965 A1
(43) Pub. Date: Jun. 11, 2015

(54) SYSTEM AND METHOD OF MANAGING COOLING ELEMENTS TO PROVIDE HIGH VOLUMES OF COOLING

(71) Applicants: Michael J. Parrella, Weston, CT (US); Jonathan Parrella, Newtown, CT (US); Martin A. Shimko, Quechee, VT (US)

(72) Inventors: Michael J. Parrella, Weston, CT (US); Jonathan Parrella, Newtown, CT (US); Martin A. Shimko, Quechee, VT (US)

(73) Assignee: GTHERM INC., Westport, CT (US)

(21) Appl. No.: 14/114,939

(22) PCT Filed: May 4, 2012
(86) PCT No.: PCT/US12/36498

§ 371 Date: Jan. 28, 2015

Related U.S. Application Data
(60) Provisional application No. 61/482,332, filed on May 4, 2011.

(51) Int. Cl. H05K 7/20; F28F 27/00; F28D 15/02

(52) U.S. Cl. CPC H05K 7/20945; F28D 15/02; F28F 27/00; H05K 7/20318; H05K 7/20327; H05K 7/20336; H05K 7/20936

(57) ABSTRACT

In combination, an electrical generation system has a condenser configured to receive a condenser cooling fluid for cooling the condenser and provide the condenser cooling fluid for re-cooling; a cooling reservoir receives a re-cooled condenser cooling fluid and provides the re-cooled condenser cooling fluid as the condenser cooling fluid; and a multiphase cooling nest receives in a first cooling phase the condenser cooling fluid; and either provides a first cooling phase fluid as the re-cooled condenser cooling fluid to the cooling reservoir for recirculating to the condenser, or provides the first fluid cooling fluid for further cooling by the multiphase cooling nest, based on the temperature of the first stage cooling fluid. The multiphase cooling nest includes a further cooling stage that receives the first cooling stage fluid, and either provides a further cooling stage fluid as the re-cooled condenser cooling fluid to the cooling reservoir for recirculating to the condenser in the electrical generation system, or provides the further cooling stage fluid for subsequent further cooling by the multiphase cooling nest, based on the temperature of the further cooling stage fluid.

### CROSS REFERENCE TO RELATED APPLICATIONS

This application claims benefit to provisional patent application Ser. No. 61/482,332, filed 4 May 2011, which is hereby incorporated by reference in its entirety.

### BACKGROUND OF THE INVENTION

1. Field of Invention

The present invention relates to the field of providing managed cooling elements, e.g., used for the generation of electricity or other applications where potentially large amounts of cooling is required.

2. Description of Related Art

Many applications require a cooling cycle where hot gases or fluids or other mediums need to be cooled or condensed as part of the application solution. Examples of this are power generation plants that have to condense steam back into water after the steam has passed through the turbine which drives the generator (or other similar systems using a range of fluids for various temperature and pressure operation). Many places in the world have little or no water and others have environmental restrictions that require that water used for cooling must be returned to the source at acceptable temperature increases. In view of this, there is a need in the industry at reducing or eliminating the use of water and if water is used to reduce the increase in temperature it has acquired during the cooling cycle.

Moreover, FIG. 1 shows and represents current forms of low volume cooling and heating, the “heat pump” systems are available today and provide lower levels of heating and cooling. Besides, FIG. 6 shows a standard heat pump coiled pipe installation that is used and known in the art.

### BRIEF SUMMARY OF THE INVENTION

The present invention is targeted at reducing or eliminating the use of water and if water is used to reduce the increase in temperature it has acquired during the cooling cycle.

The present invention provides techniques, including apparatus, a system and a method, of managing cooling elements to provide high volumes of cooling, and if necessary reduce or eliminate water usage, and if water is used, to lower the temperature of return water when water flow from a natural source is used for cooling. The system is also referred to herein as the Coldnest™.

The present invention (“ColdNest™”) relates generally to the field of providing managed cooling elements used for the generation of electricity or other applications where potentially large amounts of cooling is required. Another invention objective is to reduce or eliminate water usage or if water is used to reduce the increase in temperature of the water after it is used for cooling. Usage means the water into the system is greater than the water out of the system. As an example the use of water can be because of evaporation in a water tower. When water is used from a lake, river, ocean, etc. for cooling it is generally returned at a higher temperature then when it was extracted. Permits generally have to be granted in order to use water in this way. A preferable approach is to have the water returned at close to the same temperature it was extracted.

The ColdNest™ is comprised of multiple cooling phase techniques managed by a control system that makes real time decisions on which systems are used in combinations to accomplish the cooling objective.

### A ColdNest™ Configured to Cooperate with any Heat Exchanger

According to some embodiments, the present invention may take the form of apparatus in the form of a ColdNest™ having a first cooling phase and a further cooling stage. The first cooling phase may be configured to receive in a first cooling phase a hot fluid to be cooled, e.g., including from a heat exchanger or a condenser in an electrical generation system; and either provide a first cooling stage fluid from the first cooling stage as a cold fluid, e.g., including for provisioning back to the heat exchanger or the condenser, or provide the first cooling stage fluid for further cooling, based at least partly on the temperature of the first cooling stage fluid. The further cooling stage may be configured to receive the first cooling stage fluid from the first cooling phase; and either provide a further cooling stage fluid, e.g., including for provisioning back to the heat exchanger or the condenser, or provide the further cooling stage fluid for subsequent further cooling, based at least partly on the temperature of the further cooling stage fluid.

According to some embodiments of the present invention, the first cooling phase may be an absorption chiller phase.

According to some embodiments of the present invention, the further cooling phase may include some combination of a ground cooling phase, an air cooling phase, a water cooling phase, or a cooling tower phase.

According to some embodiments of the present invention, the ground cooling phase may include an enhanced ground cooling system at least partly formed below the ground, including having some combination of cooling coils forming slinky loops, heating dispersing fins, a heat sync, heat pipes, or heat conductive material surrounding the heat pipes.

According to some embodiments of the present invention, the cooling coils forming slinky loops are formed below the ground and configured to receive a hot fluid and provide a cooler fluid; the heat dispersing fins are formed above the ground and configured to receive a hot fluid and provide a cooler fluid; the heat pipe may be formed below the ground and configured to receive heat from the ground surrounding the enhanced ground cooling system and provide the heat away from the ground surrounding the enhanced ground cooling system; the heat conductive material may be configured around some combination of the cooling coils forming slinky loops or heat pipes.

According to some embodiments of the present invention, the ColdNest™ may also include a pumping arrangement configured to receive a pump control signal from a control system and either provide the first cooling stage fluid from the first cooling stage to the heat exchanger, or provide the first cooling stage fluid from the first cooling stage to the further cooling stage for further cooling, based at least partly on if the temperature of the first cooling stage fluid is above or below a predetermined temperature.

According to some embodiments of the present invention, the first cooling phase may be configured to receive a control signal, e.g., provided from a control system, containing information about whether to provide the first cooling stage fluid, e.g., to the heat exchanger or a cooling reservoir for providing to the condenser in the electrical generation system, or to provide the first cooling stage fluid for further cooling, based at least partly on the temperature of the further cooling stage fluid.

According to some embodiments of the present invention, the further cooling phase may be configured to receive a corresponding control signal, e.g., provided from the control system, containing information about whether to provide the further cooling stage fluid, e.g., to the heat exchanger or the cooling reservoir for providing to the condenser in the electrical generation system, or to provide the further cooling stage fluid for subsequent further cooling, based at least partly on the temperature of the further cooling stage fluid.

### A ColdNest™ Configured to Cooperate with an Electrical Generation System

According to some embodiments, the present invention may take the form of apparatus in the form of a ColdNest™, which may include a multiphase cooling nest configured to receive in a first cooling phase a condenser cooling fluid used to cool a condenser in an electrical generation system; and either provide a first cooling stage fluid from the first cooling stage for recirculating to the condenser in the electrical generation system, or provide the first cooling stage fluid for further cooling by the multiphase cooling nest, based at least partly on the temperature of the first cooling stage fluid.

According to some embodiments of the present invention, the multiphase cooling nest may include a further cooling stage configured to receive the first cooling stage fluid; and either provide a further cooling stage fluid for recirculating to the condenser in the electrical generation system, or provide the further cooling stage fluid for subsequent further cooling by the multiphase cooling nest, based at least partly on the temperature of the further cooling stage fluid.

According to some embodiments of the present invention, the ColdNest™ may include one or more of the features set forth above.

### The Apparatus

According to some embodiments, the present invention may take the form of apparatus that includes in combination an electrical generation system, a cooling reservoir and a multiphase cooling nest (aka a ColdNest™). The electrical generation system may have a condenser configured to receive a condenser cooling fluid for cooling the condenser and provide the condenser cooling fluid for re-cooling. The cooling reservoir may be configured to receive a re-cooled condenser cooling fluid and provide the re-cooled condenser cooling fluid as the condenser cooling fluid. The multiphase cooling nest may be configured to receive in a first cooling phase the condenser cooling fluid; and either provide a first cooling phase fluid as the re-cooled condenser cooling fluid to the cooling reservoir for recirculating to the condenser, or provide the first fluid cooling fluid for further cooling by the multiphase cooling nest, based at least partly on the temperature of the first stage cooling fluid.

According to some embodiments of the present invention, the multiphase cooling nest may include a further cooling stage configured to receive the first cooling stage fluid, and either provide a further cooling stage fluid as the re-cooled condenser cooling fluid to the cooling reservoir for recirculating to the condenser in the electrical generation system, or provide the further cooling stage fluid for subsequent further cooling by the multiphase cooling nest, based at least partly on the temperature of the further cooling stage fluid.

According to some embodiments of the present invention, the first cooling phase may be an absorption chiller phase.

According to some embodiments of the present invention, the further cooling phase may include some combination of a ground cooling phase, an air cooling phase, a water cooling phase or a cooling tower phase.

According to some embodiments of the present invention, the ground cooling phase may include an enhanced ground cooling system at least partly formed below the ground, including having some combination of cooling coils forming slinky loops, heating dispersing fins, a heat sync, heat pipes, or heat conductive material surrounding the heat pipes.

According to some embodiments of the present invention, the cooling coils forming slinky loops are formed below the ground and configured to receive a hot fluid and provide a cooler fluid; the heat dispersing fins are formed above the ground and configured to receive a hot fluid and provide a cooler fluid; the heat pipe may be formed below the ground and configured to receive heat from the ground surrounding the enhanced ground cooling system and provide the heat away from the ground surrounding the enhanced ground cooling system; the heat conductive material may be configured around some combination of the cooling coils forming slinky loops or heat pipes.

According to some embodiments of the present invention, the apparatus may include a heat exchanger configured to provide hot fluid to the multiphase cooling nest and receive cold fluid from the multiphase cooling nest.

According to some embodiments of the present invention, the apparatus may include a heat exchanger or direct water access immersed in a water source configured to receive hot fluid from a heat exchanger and provide cold fluid to the heat exchanger.

According to some embodiments of the present invention, the apparatus may include a pumping arrangement configured to receive a pump control signal and either provide the first cooling stage fluid from the first cooling stage to the cooling reservoir for recirculating to the condenser in the electrical generation system, or provide the first cooling stage fluid from the first cooling stage to a further cooling stage for further cooling by the multiphase cooling nest, based at least partly on if the temperature of the first cooling stage fluid is above or below a predetermined temperature.

According to some embodiments of the present invention, the apparatus may further include a control system configured to receive a temperature signal containing information about the temperature of the first cooling phase fluid being cooled by the first cooling phase of the multiphase cooling nest; determine if the temperature of the first cooling stage fluid is above or below the predetermined temperature; and provide the pump control signal to the pumping arrangement in order to pump the first cooling stage fluid to the cooling reservoir if the temperature of the first cooling stage fluid is below the predetermined temperature, or in order to pump the first cooling stage fluid to the further cooling stage if the temperature of the first cooling stage fluid is above the predetermined temperature.

### Method Claims

According to some embodiments, the present invention may take the form of a method having steps for receiving in a condenser of an electrical generation system a condenser cooling fluid for cooling the condenser and providing the condenser cooling fluid for re-cooling; receiving with a cooling reservoir a re-cooled condenser cooling fluid and providing the re-cooled condenser cooling fluid as the condenser cooling fluid; and receiving in a first cooling phase of a multiphase cooling nest the condenser cooling fluid, and either providing a first cooling phase fluid as the re-cooled condenser cooling fluid from the first cooling phase to the cooling reservoir for recirculating to the condenser, or providing the first fluid cooling fluid for further cooling by the multiphase cooling nest, based at least partly on the temperature of the first stage cooling fluid.

According to some embodiments of the present invention, the method may further include receiving in a further cooling stage the first cooling stage fluid, and either providing a further cooling stage fluid as the re-cooled condenser cooling fluid to the cooling reservoir for recirculating to the condenser in the electrical generation system, or providing the further cooling stage fluid for subsequent further cooling by the multiphase cooling nest, based at least partly on the temperature of the further cooling stage fluid.

According to some embodiments of the present invention, the method may further comprise including an absorption chiller phase in the first cooling phase.

According to some embodiments of the present invention, the method may further comprise including in the further cooling phase some combination of a ground cooling phase, an air cooling phase, a water cooling phase or a cooling tower phase.

According to some embodiments of the present invention, the method may further comprise providing with a heat exchanger hot fluid to the multiphase cooling nest and receiving cold fluid from the multiphase cooling nest.

According to some embodiments of the present invention, the method may further comprise including in the ground cooling phase an enhanced ground cooling system at least partly formed below the ground, and having some combination of cooling coils forming slinky loops, heating dispersing fins, a heat sync, heat pipes, or heat conductive material surrounding the heat pipes.

According to some embodiments of the present invention, the method further comprises forming the cooling coils forming slinky loops below the ground in order to receive a hot fluid and provide a cooler fluid; forming the heat dispersing fins above the ground in order to receive a hot fluid and provide a cooler fluid; forming the heat pipe below the ground in order to receive heat from the ground surrounding the enhanced ground cooling system and provide the heat away from the ground surrounding the enhanced ground cooling system; and/or configuring the heat conductive material around some combination of the cooling coils forming slinky loops or heat pipes.

According to some embodiments of the present invention, the method further include immersing a heat exchanger or direct water access in a water source in order receive hot fluid from a heat exchanger and provide cold fluid to the heat exchanger.

According to some embodiments of the present invention, the method further include receiving with a pumping arrangement a pump control signal, and either providing the first cooling stage fluid from the first cooling stage to the cooling reservoir for recirculating to the condenser in the electrical generation system, or providing the first cooling stage fluid from the first cooling stage to a further cooling stage for further cooling by the multiphase cooling nest, based at least partly on if the temperature of the first cooling stage fluid is above or below a predetermined temperature.

According to some embodiments of the present invention, the method further include receiving with a control system a temperature signal containing information about the temperature of the first cooling phase fluid being cooled by the first cooling phase of the multiphase cooling nest; determining with the control system if the temperature of the first cooling stage fluid is above or below the predetermined temperature; and providing with the control system the pump control signal to the pumping arrangement in order to pump the first cooling stage fluid to the cooling reservoir if the temperature of the first cooling stage fluid is below the predetermined temperature, or in order to pump the first cooling stage fluid to the further cooling stage if the temperature of the first cooling stage fluid is above the predetermined temperature.

### Means-Plus-Function Apparatus Claim

According to some embodiments of the present invention, the invention may take the form of a method comprising: means for receiving in a condenser of an electrical generation system a condenser cooling fluid for cooling the condenser and providing the condenser cooling fluid for re-cooling; means for receiving with a cooling reservoir a re-cooled condenser cooling fluid and providing the re-cooled condenser cooling fluid as the condenser cooling fluid; and means for receiving in a first cooling phase of a multiphase cooling nest the condenser cooling fluid, and either providing a first cooling phase fluid as the re-cooled condenser cooling fluid from the first cooling phase to the cooling reservoir for recirculating to the condenser, or providing the first fluid cooling fluid for further cooling by the multiphase cooling nest, based at least partly on the temperature of the first stage cooling fluid, where the means is each case in consistent with that shown and described herein.

### The Companion Application

Finally, the present application is being filed concurrent with a companion application disclosing SWEGS-based technology adapted for use in cooling, heating, VOC remediation, mining, pasteurization and brewing applications, identified as patent application Ser. No. ______ (Atty docket no. 800-163.8-1), which claims benefit to an earlier filed provisional patent application Ser. No. 61/482,368, filed 4 May 2011 (Atty docket no. 800-163.8), which are both also incorporated by reference in their entirety.

Moreover, other SWEGS-related cases have also been filed, including U.S. Patent Publication No. US 2010/0276115 (Atty docket no. 800-163.3); US 2010/0270002 (Atty docket no. 800-163.4); US 2010/0270001 (Atty docket no. 800-163.5); and US 2010/0269501 (Atty docket no. 800-163.6), which are all incorporated hereby incorporated by reference in their entirety.

Moreover still, other SWEGS-related applications have also been filed, including U.S. provisional patent application nos. 61/576,719 (Atty docket no. 800-163.9) and 61/576,700 (Atty docket no. 800-163.10), filed 16 Dec. 2011, which are both incorporated hereby incorporated by reference in their entirety.

### BRIEF DESCRIPTION OF THE SEVERAL VIEWS OF THE DRAWING

FIG. 1 is a diagram of different ways of providing geothermal energy for a home using a heat pump that are known in the art.

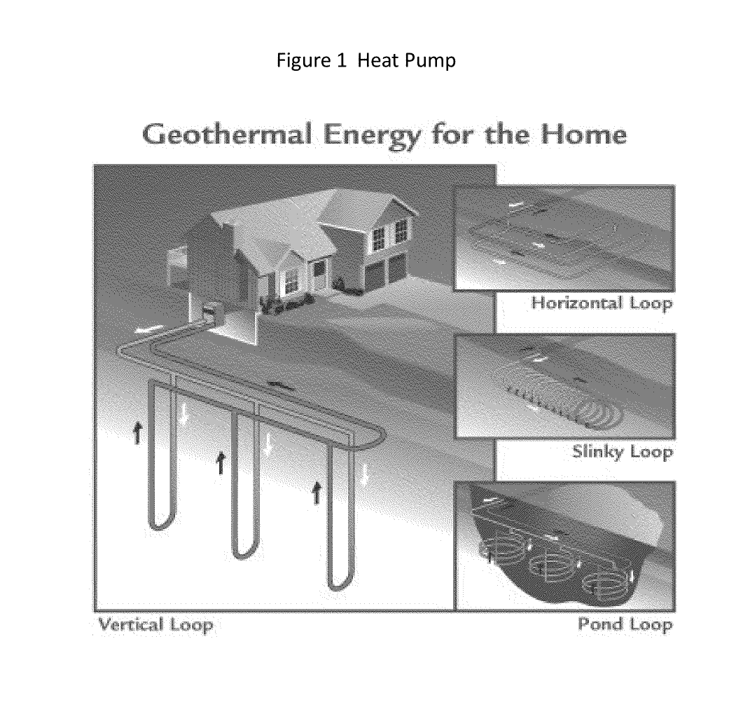

FIG. 2 is a block diagram of an example of an electric generation system, according to some embodiments of the present invention.

FIG. 3 is a block diagram of a cooling system design and control that may be implemented with a ColdNest™ according to some embodiments of the present invention.

FIG. 4 is a block diagram of a ColdNest™ supplying a cooling reservoir coupled to an electrical generation system, according to some embodiments of the present invention.

FIG. 5 is a block diagram of a ColdNest™ arranged in relation to a heat exchanger, according to some embodiments of the present invention.

FIG. 6 is a photograph of a standard heat pump coiled pipe installation that is known in the art.

FIG. 7 is a diagram of an enhanced ground cooling system, according to some embodiments of the present invention.

FIG. 8 is a diagram of an enhanced ground cooling system configured with heat sync and heat pipes, according to some embodiments of the present invention.

FIG. 9 is a diagram of a water cooling system having a heat exchanger arranged in relation to another heat exchanger or direct water access, according to some embodiments of the present invention.

FIG. 10 is a diagram of an arrangement having a single well engineered geothermal system (SWEGS) and an absorption cooler, according to some embodiments of the present invention.

### DETAILED DESCRIPTION OF THE INVENTION

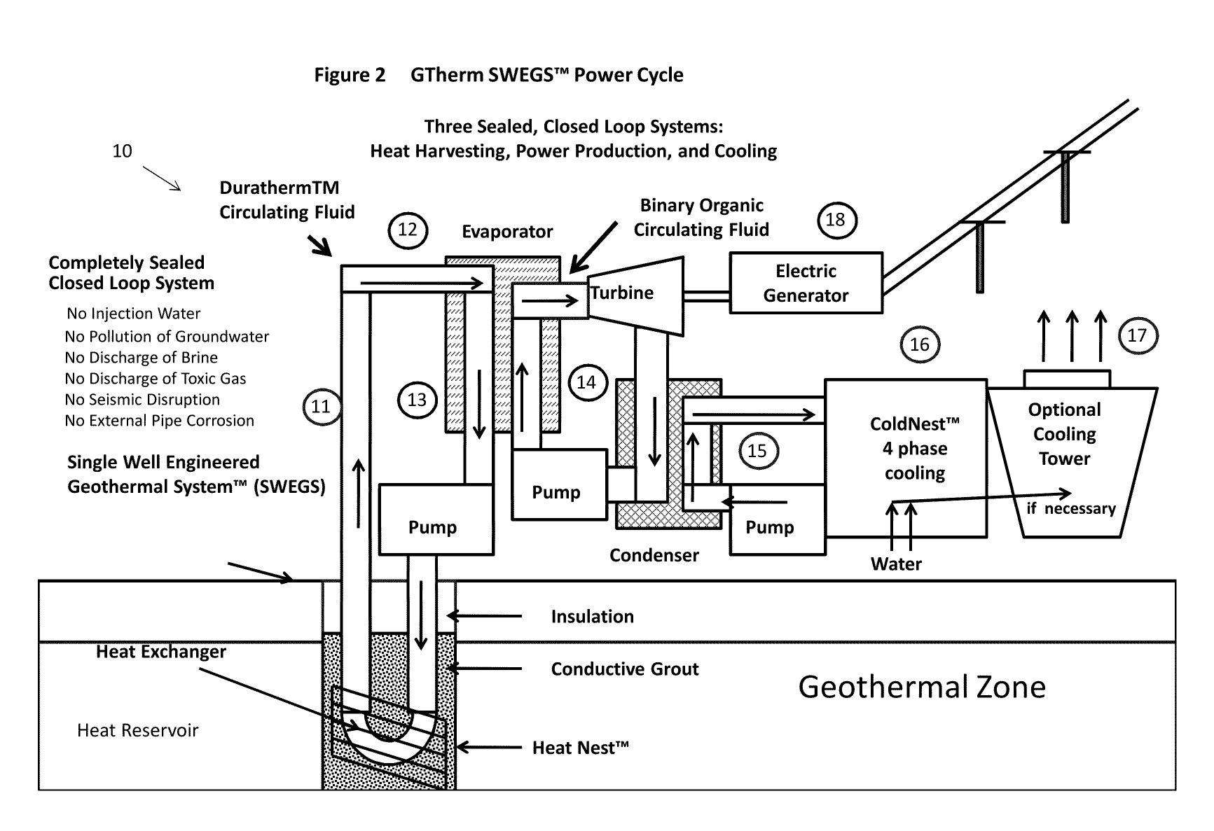

FIG. 2 is a block view of an electric generation example system generally indicated as 10 (one embodiment of the present invention) that has three loops.

A first loop (including elements 11, 12, 13) represents a heat loop which provides heat energy for the creation of steam or vapor, through an evaporator, as shown, which will power turbines.

A second loop is a power generation loop (including elements 14, 18) where the steam or vapor (vapor is from a binary fluid) drives a turbine or other engine, as shown, the turbine or engine drives an electric generator, as shown, the cooled fluid providing the heat is then returned to its source to be reheated.

A third loop (including elements 15, 16, 17) is where the steam or vapor that drives the turbine is then condensed back into fluid by going through a condenser, as shown. The cooling for the condenser is provided by the third loop (15, 16, 17) which is one embodiment of the present invention, and also known hereinafter as ColdNest™.

According to some embodiments of the present invention, the ColdNest™ may use up to four phases of cooling in collaboration and under the control of an advanced control system that coordinates each of the phases to maximize cooling. The last element of cooling may include an evaporative cooling tower which uses water to cool by evaporating it into the air. The objective is to eliminate or minimize the use of this last element.

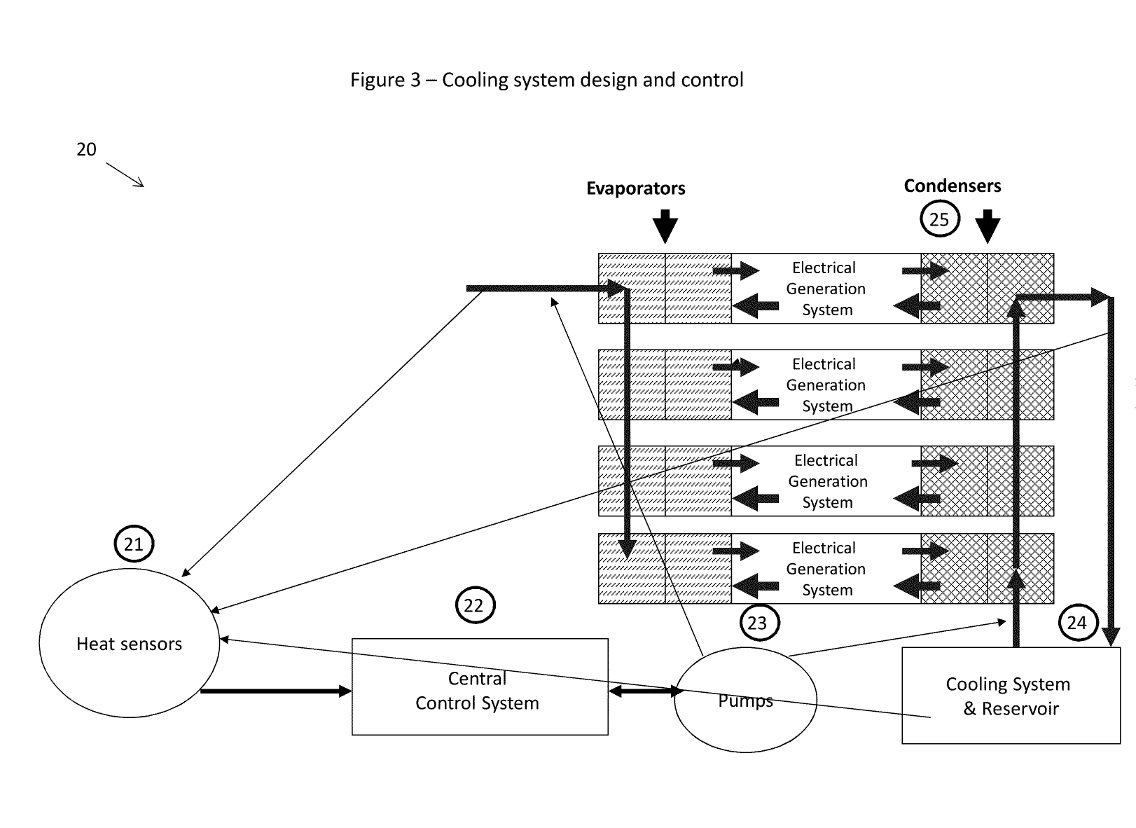

FIG. 3 is a block diagram of a flow control for a condensation cooling loop in an electrical power generation system. This control system assumes that there is a cold fluid (24) that can be used for condensation of steam or vapor (25). The central control system (22) is configured to measure the temperature, e.g., on a continuous basis, using sensors (21) and adjusts the flows of cold fluid to achieve the cooling results by adjusting the speed of the pumps (23). The present invention pertains to how the cold fluid is provided for this loop, which is the basis of the ColdNest™ invention.

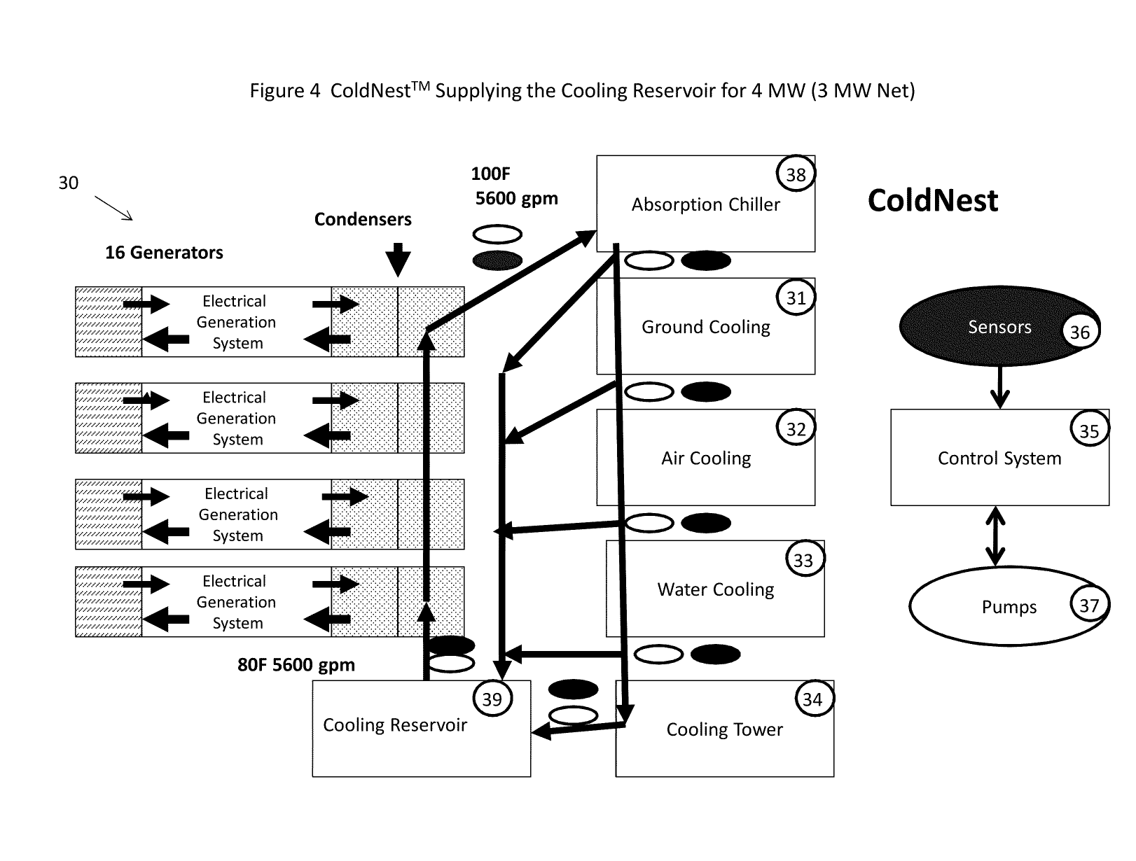

By way of example, FIG. 4 is a view of a system or arrangement generally indicated as 30 that includes a ColdNest™, according to some embodiments of the present invention, and measurement and control points (including sensors and pumps 36, 37) of up to a five cooling phase system (elements 38, 31, 32, 33, 34). In the embodiment shown in FIG. 4, ColdNest™ is understood to take the form of the five cooling phase system (elements 38, 31, 32, 33, 34). As shown, the minimum number of cooling phases where water is not required is two, i.e. the Absorptive Chiller cooling phase (38) and the ground cooling phase (31).

In FIG. 4, the ColdNest™ includes, or takes the form of, a multiphase cooling nest (31, 32, 33, 34, 38) that may be configured to receive in a first cooling phase (38) a condenser cooling fluid used to cool a condenser in an electrical generation system, as shown; and that may also be configured either to provide a first cooling stage fluid from the first cooling stage, e.g., to a cooling reservoir as shown, for recirculating to the condenser in the electrical generation system, or provide the first cooling stage fluid for further cooling by one or more further cooling phases (31, 32, 33, 34) of the multiphase cooling nest (31, 32, 33, 34, 38), based at least partly on the temperature of the first cooling stage fluid.

The multiphase cooling nest (31, 32, 33, 34, 38) may include a further cooling stage (e.g., 31) configured to receive the first cooling stage fluid; and either provide a further cooling stage fluid, e.g., to the cooling reservoir (39), for recirculating to the condenser in the electrical generation system, or provide the further cooling stage fluid for subsequent further cooling by one or more further cooling phases (32, 33, 34) of the multiphase cooling nest (31, 32, 33, 34, 38), based at least partly on the temperature of the further cooling stage fluid.

The process may by repeated, e.g., by either providing a still further cooling stage fluid, e.g., to the cooling reservoir (39), for recirculating to the condenser in the electrical generation system, or providing the still further cooling stage fluid for subsequent further cooling by one or more still further cooling phases (33, 34) of the multiphase cooling nest (31, 32, 33, 34, 38), based at least partly on the temperature of the still further cooling stage fluid.

As shown, and by way of example, the multiphase cooling nest (31, 32, 33, 34, 38) include an absorption chiller cooling phase (38), a ground cooling phase (31), an air cooling phase (32), a water cooling phase (33) and a cooling tower phase (34). However, the scope of the invention is not intended to be limited to any particular number of cooling phases, or any particular type or kind of cooling phases, either now known or later developed in the future, or any particular ordering of the cooling phases.

The system or arrangement 30 also may include a pumping arrangement having one or more pumps (37) that may configured to receive a pump control signal, e.g., from a control system (35) and either provide the first cooling stage fluid from the first cooling stage (38) to the cooling reservoir (39) for recirculating to the condenser in the electrical generation system, as shown, or provide the first cooling stage fluid from the first cooling stage (38) to a further cooling stage (31, 32, 33, 34) for further cooling by the multiphase cooling nest (38, 31, 32, 33, 34), based at least partly on if the temperature of the first cooling stage fluid is above or below a predetermined temperature. Pumping arrangements having pumps like (37) are known in the art and the scope of the invention is not intended to be limited to any particular type or kind thereof either now known or later developed in the future. The pumping arrangement is also intended to include suitable piping, couplings etc., consistent with that that would be appreciated by a person skilled in the art. The scope of the invention is also not intended to be limited to the predetermined temperature, which will be based on the particular application.

The system or arrangement 30 also may include the control system (35) configured to receive a temperature signal, e.g., from one or more sensors (36) containing information about the temperature of the first cooling phase fluid being cooled by the first cooling phase (38) of the multiphase cooling nest (38, 31, 32, 33, 34); determine if the temperature of the first cooling stage fluid is above or below the predetermined temperature; and provide the pump control signal to the pumping arrangement having the one or more pumps (37) in order to pump the first cooling stage fluid to the cooling reservoir (39) if the temperature of the first cooling stage fluid is below the predetermined temperature, or in order to pump the first cooling stage fluid to the further cooling stage (31, 32, 33, 34) if the temperature of the first cooling stage fluid is above the predetermined temperature.

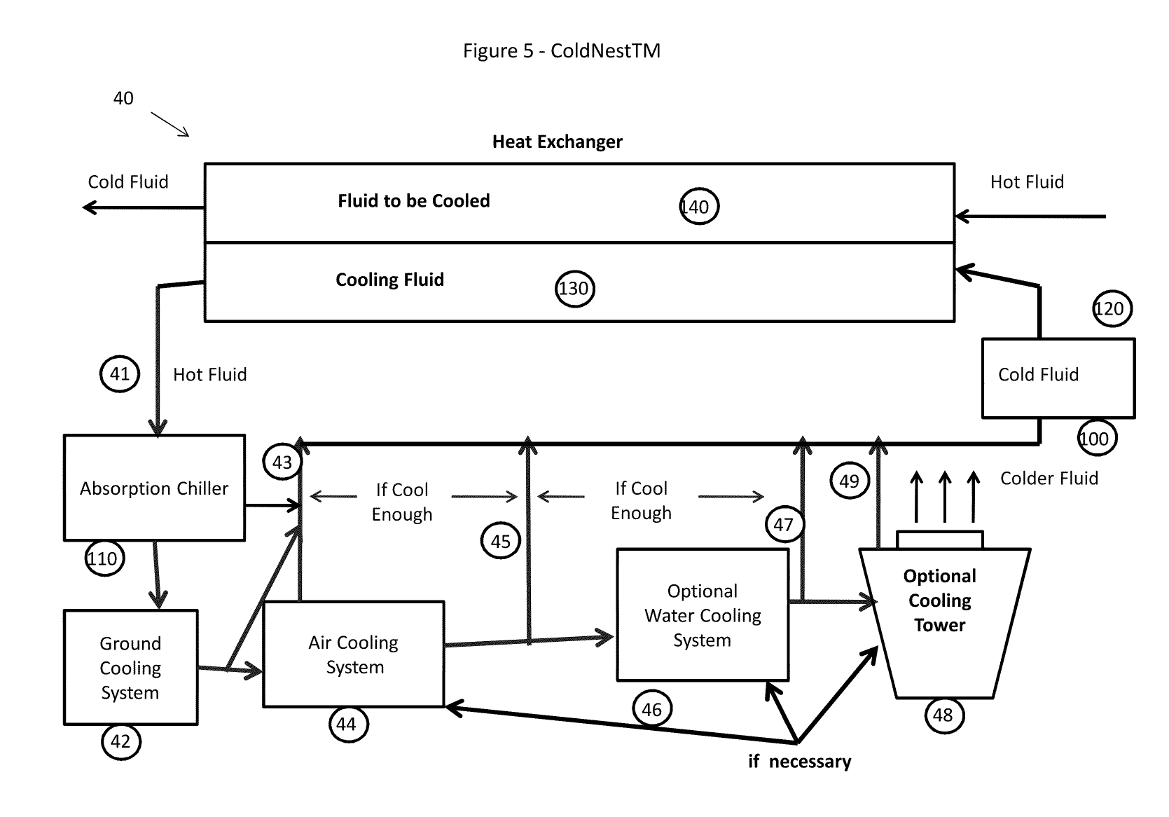

By way of example, FIG. 5 is a diagram of an arrangement or system generally indicated as 40 having a ColdNest™ (110, 42, 44, 46, 48), according to the present invention, coupled to a heat exchanger (130, 140), in a manner in which, or as, it would be used for any cooling application. In operation, the heat exchanger (130, 140) receives hot fluid and provides cold fluid, as shown. In addition, the heat exchanger (130, 140) transfers the heat and cools the fluid flow requiring a lowering of the heat content (130, 140), by providing the hot fluid (41) to a five phase ColdNest™ (110, 42, 44, 46, 48) and receiving cold or colder fluid (100, 120) back from the five phases ColdNest™ (110, 42, 44, 46, 48). Depending on the amount of heat reduction required from one to five phases (110, 42, 44, 46, 48) may be utilized, e.g., including an absorption chiller phase (110), a ground cooling system phase (42), an air cooling system phase (44), an optional water cooling system phase (46) and an optional cooling tower phase (48). Even if there are five phases (110, 42, 44, 46, 48), the cooling requirements may vary over time and some of the time more or less phases can be used (110, 42, 44, 46, 48). Using the sensors (36) in FIG. 4, the control system (35) may be configured to determine what cooling phases (110, 42, 44, 46, 48) need to be used. The arrangement or system 40 includes various fluid paths (43, 45, 47, 49) via suitable piping between the ground cooling system (42) and the air cooling system phase (44), the optional water cooling system phase (46) and the optional cooling tower phase (48). The control system (35) in FIG. 4 in configured to control the movement and flow of the fluid through the various fluid paths (43, 45, 47, 49) via suitable piping, pumping arrangement and control signaling, in a manner and way that a person skilled in the art would appreciate, based at least partly on the temperature of the fluid at the various cooling stages consistent with that set forth herein. Heat exchangers (130, 140) are known in the art, and the scope of the invention is not intended to be limited to any particular type or kind either now known or later developed in the future.

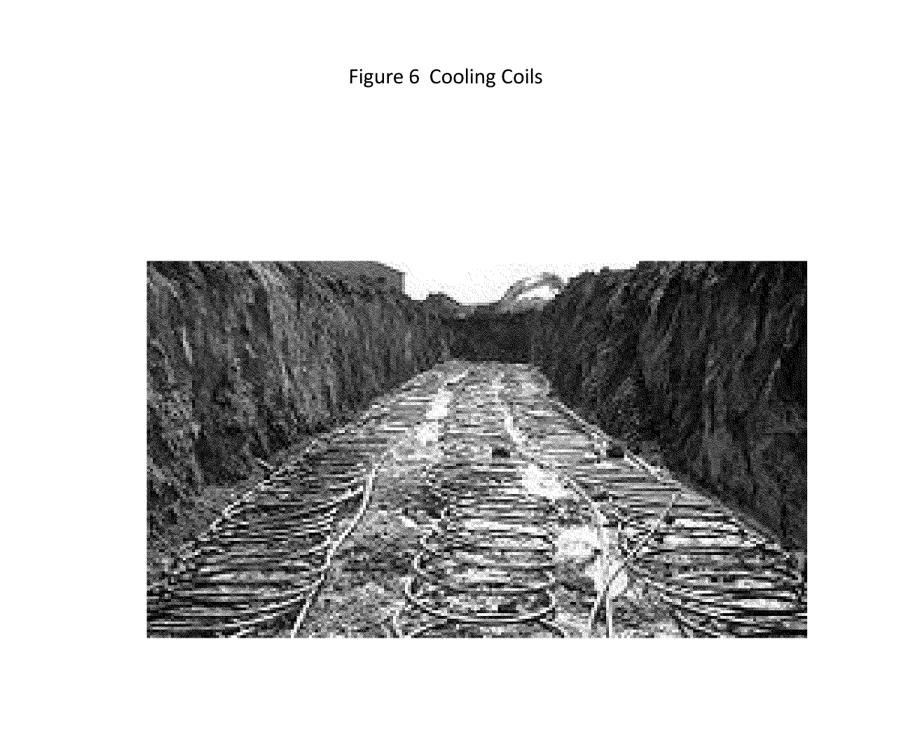

FIG. 6 shows a standard heat pump coiled pipe installation used without a ColdNest™ (this is called a slinky loop), and the Coldnest™, according to some embodiments of the present invention, may use multiple parallel channels of these loops to achieve a desired cooling capacity.

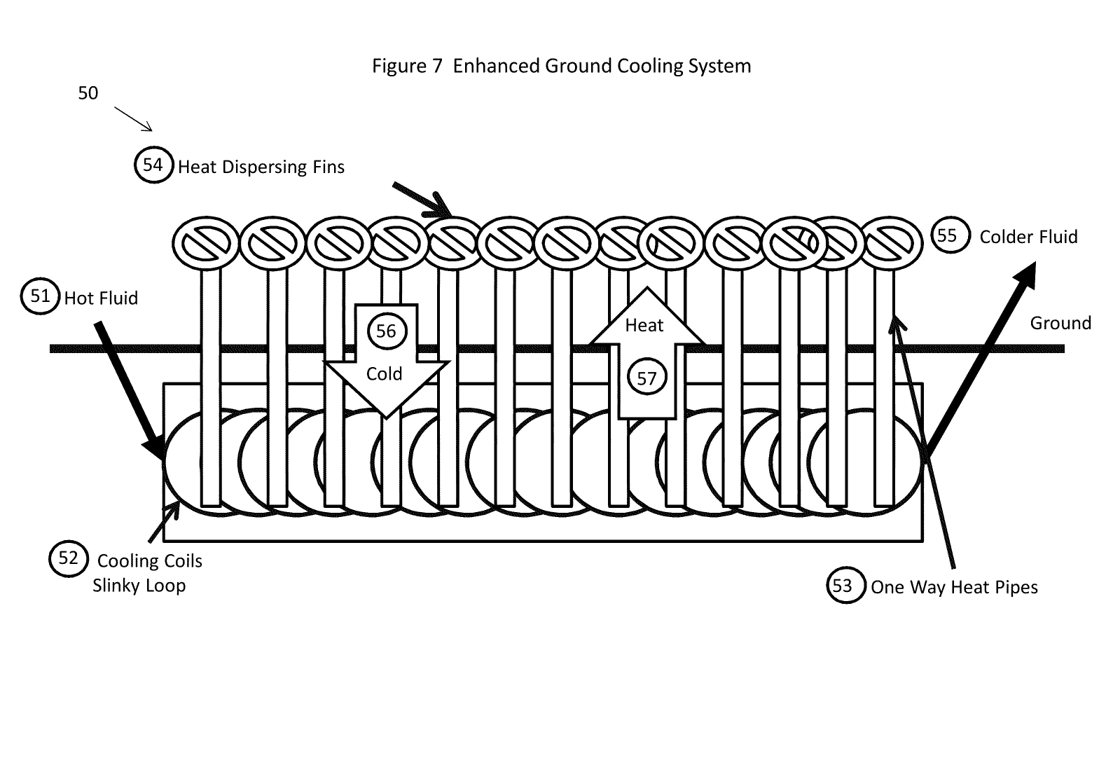

FIG. 7 shows an enhanced ground cooling system generally indicated an (50), according to some embodiments of the present invention, having a slinky loop (52) arranged below the ground, as shown. FIG. 7 also shows an inventive enhancement to the slinky loop (52), where one or more one way heat pipes (53) with heat dispersing apparatus (e.g., heat dispersing fins (54)) may be inserted in whole or in part over the length of the slinky loop (52) to remove heat from the slinky loop and disperse it in the air (53, 54). As shown, cold (56) is shown moving downwardly, and heat (57) is shown moving upwardly. The one way heat pipe (53) works when the air is cooler than the slinky loop (52) and assists the slinky loop (52) to cool the fluid traveling through the slinky loop (52). This increases the cooling capacity of the slinky loop (52) as a function of the number of one way heat pipes (53) used.

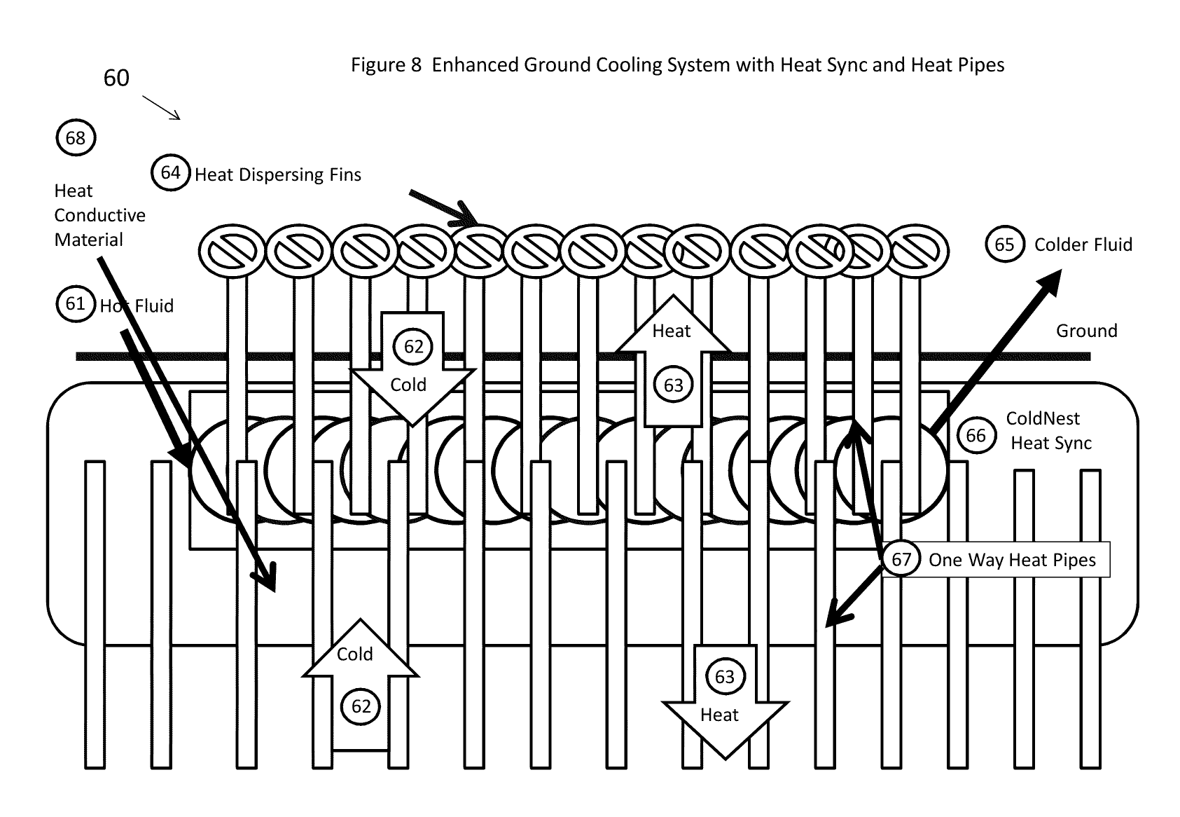

FIG. 8 shows an enhanced ground cooling system generally indicated as 60 configured with heat sync (66) and heat pipes (67), according to some embodiments of the present invention. As shown, cold (62) is shown moving upwardly/downwardly towards the heat sync (66), and heat (63) is shown moving upwardly/downwardly away from the heat sync (66). The heat sync (6) is built around the slinky loop (52) in FIG. 7. This heat sync (66) is filled with a fluid or other highly heat conductive material (68) and one way heat pipes (67) are inserted though the heat sync (66) into the earth. The heat sync (66) and the one way heat pipes (67) substantially and dramatically increase the heat dissipating capacity of the slinky loop (52) in FIG. 7.

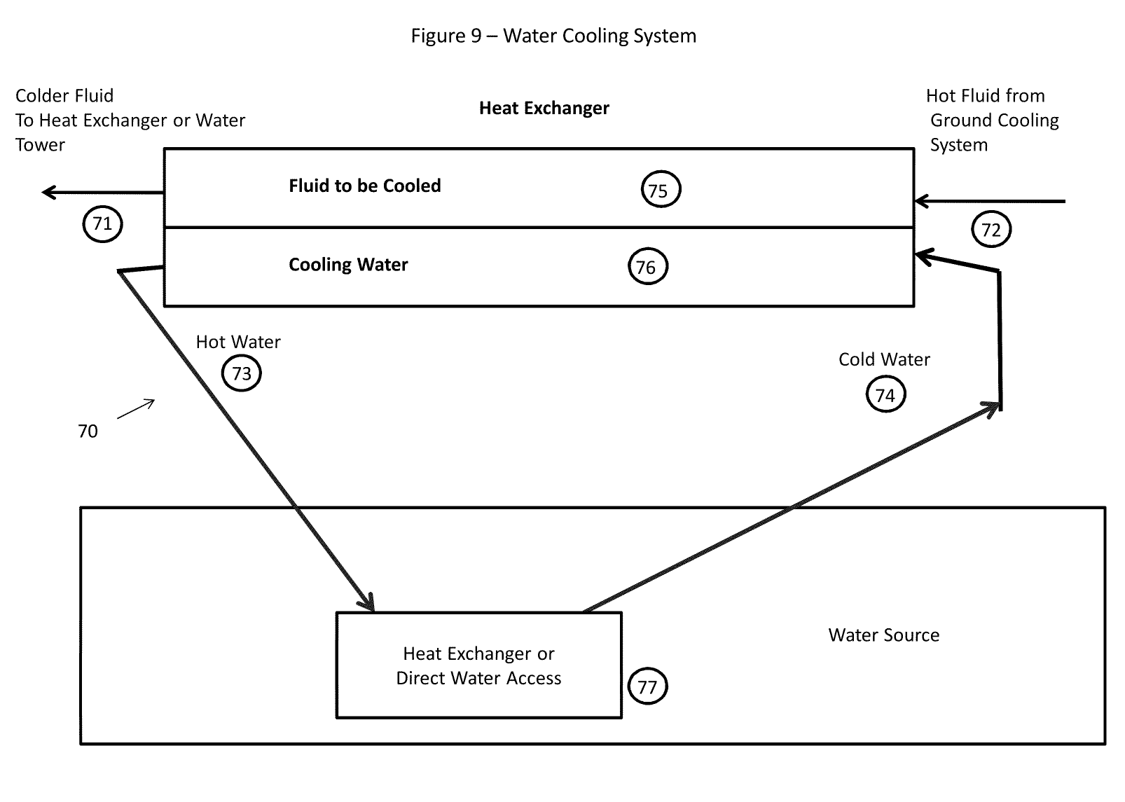

FIG. 9: is a water cooling system generally indicated as 70 having a heat exchanger (75. 76) arranged in relation to another heat exchanger or direct water access (77), according to some embodiments of the present invention. In the water cooling loop 70, the heat exchanger (75, 76) provides hot water (73) to the heat exchanger or direct water access (77), and receives back cold water (74). The heat exchanger or direct water access (77) is immersed in a water source, and utilizes the cooler temperature of the water source and delivers the cooling through the second heat exchanger (75, 76).

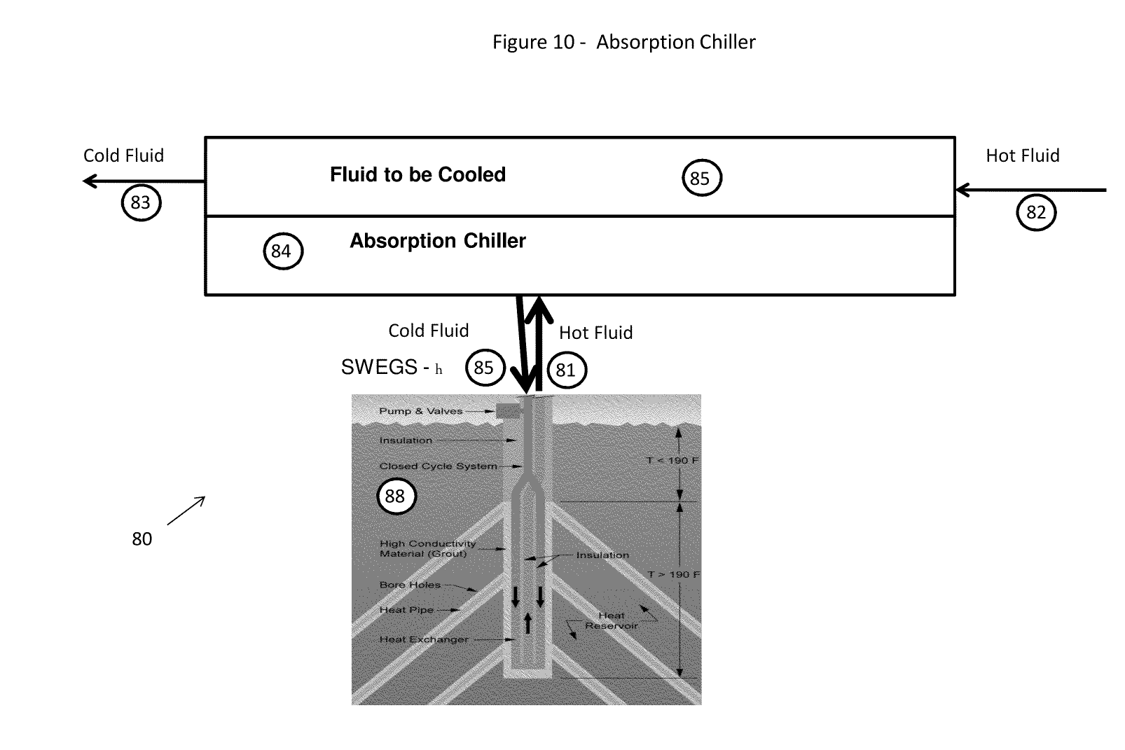

FIG. 10: is an arrangement generally indicated as 80 having a single well engineered geothermal system (88, SWEGS) and an absorption chiller or cooler (84), according to some embodiments of the present invention, which provides an inventive adaptation utilizing an absorptive chiller phase that is driven by the heat from the SWEGS (88). The SWEGS (88) delivers heat in the form of hot fluid (81) to the absorptive chiller (84) which acts upon the liquid requiring cooling. The temperature of the cooled fluid can be much lower than can be achieved by direct ambient fluid cooling methods and, in the case of a power cycle, may significantly increase power output of the system. (85). The fluid from the well that powers the chiller (85) is returned through a closed loop back as cold fluid down the well for re-heating.

### ColdNest™ Description

### Definition

The ColdNest™ concept according to the present invention can use all of the potential cooling processes for an application like an electric generating plant to provide the most cost effective way of delivering the required cooling for a condenser (see FIG. 2). The reason for taking this approach is to deal with the reality of the need to reduce or eliminate the amount of water lost in an evaporative process or when environmental conditions or water availability constrain the extent to which water can be used in a “once-through”, liquid heat sink, or evaporative cooling system. The processes considered in the ColdNest™ are as follows:

### Absorptive Chiller Cooling

Absorption chillers use heat, instead of mechanical energy, to provide cooling (see FIG. 10 (84)). The mechanical vapor compressor is replaced by a thermal compressor that may consist of an absorber, a generator, a pump, and a throttling device. The refrigerant vapor from the evaporator is absorbed by a solution mixture in the absorber. This solution is then pumped to the generator where the refrigerant is re-vaporized using a heat source. The refrigerant-depleted solution is then returned to the absorber via a throttling device. The two most common refrigerant/absorbent mixtures used in absorption chillers are water/lithium bromide and ammonia/water. Compared to mechanical chillers, absorption chillers have a low coefficient of performance (COP=chiller load/heat input). Nonetheless, they can substantially reduce operating costs because they are energized by heat, while vapor compression chillers must be motor or engine-driven. Low-pressure absorption chillers are available in capacities ranging from 100 to 1,500 tons. Absorption chillers come in two commercially available designs: single-effect and double-effect. Single-effect machines provide a thermal COP of 0.7 and require about 18 pounds of 15-psig steam per ton-hour of cooling. Double-effect machines are about 40 percent more efficient, but require a higher grade of thermal input, using about 10 pounds of 100- to 150-psig steam per ton-hour. Absorption chillers can reshape facility thermal and electric load profiles by shifting cooling from an electric to a thermal load. The heat from a SWEGS, see FIG. 10 (88)) is supplied to the absorptive chiller (see FIG. 10 (81)). The heat is used to drive the thermal compressors in the chiller (see FIG. 10 (85)). The fluid from the SWEGS is returned to the well for re-heating (see FIG. 10 (85)). The ColdNest™ control system (see FIG. 4 (35)) determines whether the absorptive chiller cooling system has cooled the fluid enough to satisfy the cooling requirement. If it has the cooled fluid is directed to the heat exchanger, if not it is directed to the ground cooling system (see FIG. 4 (31)).

### Ground Cooling (31, 42), FIGS. 4-5

Similar air conditioning and heating systems, the ground itself can be an effective sink for cooling a closed loop fluid system. A typical heat pump system has a vertical closed loop field composed of pipes that run vertically in the ground. A hole is bored in the ground, typically {{convert|75|to-|500|ft}} deep. Pipe pairs in the hole are joined with a U-shaped cross connector at the bottom of the hole. The borehole is commonly filled with a grout surrounding the pipe to provide a thermal connection to the surrounding soil or rock to improve the heat transfer. Thermally enhanced grouts are available to improve this heat transfer. Grout also protects the ground water from contamination, and prevents artesian wells from flooding the property. Vertical loop fields are typically used when there is a limited area of land available. Bore holes are spaced 5-6 m apart and the depth depends on ground and building characteristics.

A more efficient system is the slinky loops that run out horizontally depicted in FIG. 6. A horizontal closed loop field is composed of pipes that run horizontally in the ground. A long horizontal trench, deeper than the frost line, is dug and slinky coils are placed horizontally inside the same trench. Excavation for horizontal loop fields is about half the cost of vertical drilling, so this is the most common layout used wherever there is adequate land available. One way of picturing a slinky field is to imagine holding a slinky on the top and bottom with your hands and then move your hands in opposite directions. Rather than using straight pipe, slinky coils, use overlapped loops of piping laid out horizontally along the bottom of a wide trench. Depending on soil, climate and your heat requirement slinky coil trenches can be anywhere from one third to two thirds shorter than traditional horizontal loop trenches. Slinky coil ground loops are essentially a more economic and space efficient version of a horizontal ground loop. This sink can be used continuously throughout the year because of the conductive ability to dissipate heat. It can also be applied to eliminate water use at high load, high ambient air temperature conditions, or throughout the summer months to minimize water use. Applying this known heat sink approach to MW scale electric power production is an innovation that will require several inventive additions to the current slinky loop implementation.

According to some embodiments of the present invention, one inventive addition is the installation of one way heat pipes form the air to the slinky loop buried in the ground (see FIG. 7 (53)). Attached to the air end is a heat dissipating apparatus (fins (54) is an example of such apparatus, FIG. 7 (54)). The heat pipes (53) are one way which means they only work when the air temperature is colder than the heat in the earth and the slinky loop.

According to some embodiments of the present invention, a second inventive addition is to install a heat sync (66) around the slinky loop (52) made up of highly heat conductive material (FIG. 8 (68)), this heat sync (66) will expand the reach of the slinky loop (52) into the cool earth around the slinky loop (52) and enhance the operations of the air to earth heat pipes (67). The heat sync (66) will also absorb the heat from the air to earth heat pipes (67) and more effectively transfer the heat to the cooler earth. When the air is cool and the earth is hotter (occurs in winter and at night) the air to earth heat pipes (67) may build up a reserve of coldness depending on the cooling demand (like a battery of coldness) by using the heat conductive material (68) and the earth.

According to some embodiments of the present invention, a third inventive addition is the installation of one way heat pipes (FIG. 8 (67)) from the high heat conductive heat sync (66) into the earth. These heat pipes (67) only work when the far earth is cooler than the heat sync (66) and the slinky loop (52). These heat pipes (67) extend the ability of using the earth to cool by significant extending the amount of earth that is accessed.

The ColdNest™ control system (FIG. 4 (35)) determines whether the absorption chiller (38) and ground system has cooled the fluid enough to satisfy the cooling requirement. If it has, then the cooled fluid is directed to the heat exchanger, i.e. the cooling reservoir (39) in FIG. 4, or the heat exchanger (130, 140) in FIG. 5; if not, then it is directed to the air cooling system (32) in FIG. 4 or (44) in FIG. 5.

### Air Cooling 32, 44 (FIGS. 4-5)

Though not as efficient as water cooling because of the reduced heat transfer coefficients relative to water, this cooling method has very limited environmental impact and does not use water. Therefore in the heat nest approach, a separate, closed water fluid is circulated first through the condenser where it removes heat and is warmed, and then to an air heat exchanger to be re-cooled. Depending on the air conditions this approach will not be able to satisfy the entire cooling load at all times of the year (generally in the summer months). This is especially true for the low temperature conversion systems targeted by the ColdNest™, according to the present invention The ColdNest control system (FIG. 4 (35)) is configured to determine whether the air cooling system has cooled the fluid enough to satisfy the cooling requirement. If it has, the cooled fluid is directed to the heat exchanger, i.e. the cooling reservoir (FIG. 4, 39); if not, it is directed to the ground cooling system (FIG. 4 (31)).

### Water Cooling Direct Access, FIG. 9

Water is pumped directly from a water source, as shown, to the heat exchanger (FIG. 9 (75, 76)) or a double heat exchanger method is used (FIG. 9 (76, 77)). The heat exchanger cools off the cooling fluid used in the ColdNest™ system (see FIG. 5 (110, 42, 44, 46, 48)) No water is lost in the process. Water availability, pulling native animal life into the cooling loop, and the environmental impact of the warm return water are considered.

### Water Cooling with Heat Exchanger

A separate, closed water loop is circulated first through the heat exchanger (see FIG. 5 (130, 140)) where it removes heat and is warmed, and then to a heat exchanger in a water source (pond or steam FIG. 9 (77)). This is somewhat less efficient than the direct method because of the addition of another heat exchange process. Water availability and the environmental impact of the warm return water are considered, but the potential for physically involving and harming the native animal life is eliminated.

The ColdNest™ control system (see FIG. 4 (35)) is configured to determine whether the water cooling system has cooled the fluid enough to satisfy the cooling requirement. If it has, the cooled fluid is directed to the heat exchanger, if not it is directed to the water cooling tower system (see FIG. 4 (34), FIG. 5 (48)).

### Water Tower Evaporative Cooling

This standard cooling approach is the most efficient method, but has significant environmental effects in terms of water loss to evaporation (and the subsequent issues of high humidity plumes). This is the last method used in the implementation of the Cold Nest, where minimization of water loss is generally critical.

### Cold Nest Implementation

For the purposes of this description we will assume that the restrictions on water use limit both the application of evaporative and water based heat sink methods. Clearly there are many possible design scenarios that are dependent on specific site constraints. The figure below shows the general implementation of the Cold Nest approach.

First, the absorptive chiller cooling approach is evaluated using, e.g., the following technique. A minimum temperature differential is selected for the heat exchange process. Then the potential for absorptive cooling is calculated using the heat equilibrium values of the SWEGS. Once the worst case condition is calculated for the chiller cooling an optimum design is established for ground cooling. The cooling potential of the ground loop is subtracted from the cooling remaining after chiller cooling to get the maximum remaining cooling load at anytime during the month. The individual cooling load for the month is then recalculated (as above) and the heat dissipation requirements are determined. If necessary the air cooling approach is applied. A minimum temperature differential is selected for the air heat exchange process. Then the potential for air cooling is calculated by using the average high and low air temperature for a given month to calculate the % of time that the air temperature s below a given temperature. The results are tabulated monthly and the total heat removed each month is calculated. The peak cooling load remaining at the most adverse condition in the month (minimum air cooling) is calculated by the fraction of temperature decrease in the fluid flow achievable in this condition. This sets the heat dissipation required for the rest of the system. If there is more heat dissipation required the peak water flow (liquid heat sink cooling) or evaporative rate (cooling tower) is calculated for each month. The design criterion is to eliminate the water cooling needs, but it is not always possible. For the case in which evaporative cooling is used, the total is summed and used to calculate the acre feet of water evaporated each year. Based on these heat dissipations rate requirements the individual cooling process equipment can be designed.

TABLE I
Water Consumption Estimates per MWe Output

| | Peak Water | Annual Water |
|---|---|---|
| | Flow Required | Consumption (acre |
| Cooling Approach | (gpm) | feet) |
| Evaporative Cooling Only | 29 | 47 |
| Once Thru Water Only* | 1041 | 0 |
| Air/Evaporative Hybrid | 29 | 18 |
| Air/Ground/Evaporative Hybrid | 29 | 10 |
| Water Sink Only\hat{ } | 1230 | 0 |
| Air/Water Sink | 1230 | 0 |
| Air/Ground/Water Sink | 923 | 0 |

*Assume 26° C. Temperature Rise of Cooling Water
\hat{ }Assume 22° C. Temperature Rise of Cooling Water

### Scope of the Invention

It should be understood that, unless stated otherwise herein, any of the features, characteristics, alternatives or modifications described regarding a particular embodiment herein may also be applied, used, or incorporated with any other embodiment described herein. Also, the drawing herein is not necessarily drawn to scale.

Although the invention has been described and illustrated with respect to exemplary embodiments thereof, the foregoing and various other additions and omissions may be made therein and thereto without departing from the spirit and scope of the present invention.
ColdNest Claims

1. A ColdNest comprising:
a multiphase cooling nest configured to
receive in a first cooling phase a condenser cooling fluid used to cool a condenser in an electrical generation system; and
either provide a first cooling stage fluid from the first cooling stage for recirculating to the condenser in the electrical generation system, or provide the first cooling stage fluid for further cooling by the multiphase cooling nest, based at least partly on the temperature of the first cooling stage fluid.

2. A ColdNest according to claim 1, wherein the multiphase cooling nest comprises a further cooling stage configured to
receive the first cooling stage fluid; and
either provide a further cooling stage fluid for recirculating to the condenser in the electrical generation system, or provide the further cooling stage fluid for subsequent further cooling by the multiphase cooling nest, based at least partly on the temperature of the further cooling stage fluid.

3. A ColdNest according to claim 1, wherein the first cooling phase is an absorption chiller phase.

4. A ColdNest according to claim 1, wherein the further cooling phase includes some combination of a ground cooling phase, an air cooling phase, a water cooling phase, or a cooling tower phase.

5. A ColdNest according to claim 4, wherein the ground cooling phase comprises an enhanced ground cooling system at least partly formed below the ground, including having some combination of cooling coils forming slinky loops, heating dispersing fins, a heat sync, heat pipes, or heat conductive material surrounding the heat pipes.

6. A ColdNest according to claim 5, wherein the cooling coils forming slinky loops are formed below the ground and configured to receive a hot fluid and provide a cooler fluid.

7. A ColdNest according to claim 5, wherein the heat dispersing fins are formed above the ground and configured to receive a hot fluid and provide a cooler fluid.

8. A ColdNest according to claim 5, wherein the heat pipe is formed below the ground and configured to receive heat from the ground surrounding the enhanced ground cooling system and provide the heat away from the ground surrounding the enhanced ground cooling system.

9. A ColdNest according to claim 5, wherein the heat conductive material is configured around some combination of the cooling coils forming slinky loops or heat pipes.

10. A ColdNest according to claim 1, wherein the ColdNest comprises:
a pumping arrangement configured to receive a pump control signal from a control system and either provide the first cooling stage fluid from the first cooling stage to a cooling reservoir for recirculating to the condenser in the electrical generation system, or provide the first cooling stage fluid from the first cooling stage to a further cooling stage for further cooling by the multiphase cooling nest, based at least partly on if the temperature of the first cooling stage fluid is above or below a predetermined temperature.
An Electrical Generation System

11. Apparatus comprising:
an electrical generation system having a condenser configured to receive a condenser cooling fluid for cooling the condenser and provide the condenser cooling fluid for re-cooling;
a cooling reservoir configured to receive a re-cooled condenser cooling fluid and provide the re-cooled condenser cooling fluid as the condenser cooling fluid; and
a multiphase cooling nest configured to receive in a first cooling phase the condenser cooling fluid; and either provide a first cooling phase fluid as the re-cooled condenser cooling fluid to the cooling reservoir for recirculating to the condenser, or provide the first fluid cooling fluid for further cooling by the multiphase cooling nest, based at least partly on the temperature of the first stage cooling fluid.

12. Apparatus according to claim 11, wherein the multiphase cooling nest comprises a further cooling stage configured to receive the first cooling stage fluid, and either provide a further cooling stage fluid as the re-cooled condenser cooling fluid to the cooling reservoir for recirculating to the condenser in the electrical generation system, or provide the further cooling stage fluid for subsequent further cooling by the multiphase cooling nest, based at least partly on the temperature of the further cooling stage fluid.

13. Apparatus according to claim 11, wherein the first cooling phase is an absorption chiller phase.

14. Apparatus according to claim 11, wherein the further cooling phase includes some combination of a ground cooling phase, an air cooling phase, a water cooling phase or a cooling tower phase.

15. Apparatus according to claim 11, wherein the apparatus comprises a heat exchanger configured to provide hot fluid to the multiphase cooling nest and receive cold fluid from the multiphase cooling nest.

16. Apparatus according to claim 14, wherein the ground cooling phase comprises an enhanced ground cooling system at least partly formed below the ground, including having some combination of cooling coils forming slinky loops, heating dispersing fins, a heat sync, heat pipes, or heat conductive material surrounding the heat pipes.

17. Apparatus according to claim 16, wherein the cooling coils forming slinky loops are formed below the ground and configured to receive a hot fluid and provide a cooler fluid.

18. Apparatus according to claim 16, wherein the heat dispersing fins are formed above the ground and configured to receive a hot fluid and provide a cooler fluid.

19. Apparatus according to claim 16, wherein the heat pipe is formed below the ground and configured to receive heat from the ground surrounding the enhanced ground cooling system and provide the heat away from the ground surrounding the enhanced ground cooling system.

20. Apparatus according to claim 16, wherein the heat conductive material is configured around some combination of the cooling coils forming slinky loops or heat pipes.

21. Apparatus according to claim 11, wherein the apparatus comprises a heat exchanger or direct water access immersed in a water source configured to receive hot fluid from a heat exchanger and provide cold fluid to the heat exchanger.

22. Apparatus according to claim 11, wherein the apparatus comprises:
a pumping arrangement configured to receive a pump control signal and either provide the first cooling stage fluid from the first cooling stage to the cooling reservoir for recirculating to the condenser in the electrical generation system, or provide the first cooling stage fluid from the first cooling stage to a further cooling stage for further cooling by the multiphase cooling nest, based at least partly on if the temperature of the first cooling stage fluid is above or below a predetermined temperature.

23. Apparatus according to claim 22, where the apparatus further comprises:
a control system configured to
receive a temperature signal containing information about the temperature of the first cooling phase fluid being cooled by the first cooling phase of the multiphase cooling nest;
determine if the temperature of the first cooling stage fluid is above or below the predetermined temperature; and
provide the pump control signal to the pumping arrangement in order to pump the first cooling stage fluid to the cooling reservoir if the temperature of the first cooling stage fluid is below the predetermined temperature, or in order to pump the first cooling stage fluid to the further cooling stage if the temperature of the first cooling stage fluid is above the predetermined temperature.
Method Claims

24. A method comprising:
receiving in a condenser of an electrical generation system a condenser cooling fluid for cooling the condenser and providing the condenser cooling fluid for re-cooling;
receiving with a cooling reservoir a re-cooled condenser cooling fluid and providing the re-cooled condenser cooling fluid as the condenser cooling fluid; and
receiving in a first cooling phase of a multiphase cooling nest the condenser cooling fluid, and either providing a first cooling phase fluid as the re-cooled condenser cooling fluid from the first cooling phase to the cooling reservoir for recirculating to the condenser, or providing the first fluid cooling fluid for further cooling by the multiphase cooling nest, based at least partly on the temperature of the first stage cooling fluid.

25. A method according to claim 24, wherein the method further comprises receiving in a further cooling stage the first cooling stage fluid, and either providing a further cooling stage fluid as the re-cooled condenser cooling fluid to the cooling reservoir for recirculating to the condenser in the electrical generation system, or providing the further cooling stage fluid for subsequent further cooling by the multiphase cooling nest, based at least partly on the temperature of the further cooling stage fluid.

26. A method according to claim 24, wherein the method further comprises including an absorption chiller phase in the first cooling phase.

27. A method according to claim 24, wherein the method further comprises including in the further cooling phase some combination of a ground cooling phase, an air cooling phase, a water cooling phase or a cooling tower phase.

28. A method according to claim 24, wherein the method further comprises providing with a heat exchanger hot fluid to the multiphase cooling nest and receiving cold fluid from the multiphase cooling nest.

29. A method according to claim 27, wherein the method further comprises including in the ground cooling phase an enhanced ground cooling system at least partly formed below the ground, and having some combination of cooling coils forming slinky loops, heating dispersing fins, a heat sync, heat pipes, or heat conductive material surrounding the heat pipes.

30. A method according to claim 29, wherein the method further comprises forming the cooling coils forming slinky loops below the ground in order to receive a hot fluid and provide a cooler fluid.

31. A method according to claim 29, wherein the method further comprises forming the heat dispersing fins above the ground in order to receive a hot fluid and provide a cooler fluid.

32. A method according to claim 29, wherein the method further comprises forming the heat pipe below the ground in order to receive heat from the ground surrounding the enhanced ground cooling system and provide the heat away from the ground surrounding the enhanced ground cooling system.

33. A method according to claim 29, wherein the method further comprises configuring the heat conductive material around some combination of the cooling coils forming slinky loops or heat pipes.

34. A method according to claim 24, wherein the method further comprises immersing a heat exchanger or direct water access in a water source in order receive hot fluid from a heat exchanger and provide cold fluid to the heat exchanger.

35. A method according to claim 24, wherein the method further comprises receiving with a pumping arrangement a pump control signal, and either providing the first cooling stage fluid from the first cooling stage to the cooling reservoir for recirculating to the condenser in the electrical generation system, or providing the first cooling stage fluid from the first cooling stage to a further cooling stage for further cooling by the multiphase cooling nest, based at least partly on if the temperature of the first cooling stage fluid is above or below a predetermined temperature.

36. A method according to claim 35, where the method further comprises:
receiving with a control system a temperature signal containing information about the temperature of the first cooling phase fluid being cooled by the first cooling phase of the multiphase cooling nest;
determining with the control system if the temperature of the first cooling stage fluid is above or below the predetermined temperature; and
providing with the control system the pump control signal to the pumping arrangement in order to pump the first cooling stage fluid to the cooling reservoir if the temperature of the first cooling stage fluid is below the predetermined temperature, or in order to pump the first cooling stage fluid to the further cooling stage if the temperature of the first cooling stage fluid is above the predetermined temperature.
Means-Plus-Function Apparatus Claim

37. A method comprising:
means for receiving in a condenser of an electrical generation system a condenser cooling fluid for cooling the condenser and providing the condenser cooling fluid for re-cooling;
means for receiving with a cooling reservoir a re-cooled condenser cooling fluid and providing the re-cooled condenser cooling fluid as the condenser cooling fluid; and
means for receiving in a first cooling phase of a multiphase cooling nest the condenser cooling fluid, and either providing a first cooling phase fluid as the re-cooled condenser cooling fluid from the first cooling phase to the cooling reservoir for recirculating to the condenser, or providing the first fluid cooling fluid for further cooling by the multiphase cooling nest, based at least partly on the temperature of the first stage cooling fluid.
Alternative Coldnest Claims

38. A ColdNest comprising:
a first cooling phase configured to receive in a first cooling phase a hot fluid to be cooled, including from a heat exchanger or a condenser in an electrical generation system; and either provide a first cooling stage fluid from the first cooling stage as a cold fluid, including for provisioning back to the heat exchanger or the condenser, or provide the first cooling stage fluid for further cooling, based at least partly on the temperature of the first cooling stage fluid; and
a further cooling stage configured to receive the first cooling stage fluid from the first cooling phase; and either provide a further cooling stage fluid, including for provisioning back to the heat exchanger or the condenser, or provide the further cooling stage fluid for subsequent further cooling, based at least partly on the temperature of the further cooling stage fluid.

39. A ColdNest according to claim 38, wherein the first cooling phase is an absorption chiller phase.

40. A ColdNest according to claim 38, wherein the further cooling phase includes some combination of a ground cooling phase, an air cooling phase, a water cooling phase, or a cooling tower phase.

41. A ColdNest according to claim 40, wherein the ground cooling phase comprises an enhanced ground cooling system at least partly formed below the ground, including having some combination of cooling coils forming slinky loops, heating dispersing fins, a heat sync, heat pipes, or heat conductive material surrounding the heat pipes.

42. A ColdNest according to claim 41, wherein the cooling coils forming slinky loops are formed below the ground and configured to receive a hot fluid and provide a cooler fluid.

43. A ColdNest according to claim 41, wherein the heat dispersing fins are formed above the ground and configured to receive a hot fluid and provide a cooler fluid.

44. A ColdNest according to claim 41, wherein the heat pipe is formed below the ground and configured to receive heat from the ground surrounding the enhanced ground cooling system and provide the heat away from the ground surrounding the enhanced ground cooling system.

45. A ColdNest according to claim 41, wherein the heat conductive material is configured around some combination of the cooling coils forming slinky loops or heat pipes.

46. A ColdNest according to claim 38, wherein the ColdNest comprises:
a pumping arrangement configured to receive a pump control signal from a control system and either provide the first cooling stage fluid from the first cooling stage to the heat exchanger, or provide the first cooling stage fluid from the first cooling stage to the further cooling stage for further cooling, based at least partly on if the temperature of the first cooling stage fluid is above or below a predetermined temperature.

46. A ColdNest according to claim 1, wherein the first cooling phase is configured to receive a control signal, including one provided from a control system, containing information about whether to provide the first cooling stage fluid, including to the heat exchanger or a cooling reservoir for providing to the condenser in the electrical generation system, or to provide the first cooling stage fluid for further cooling, based at least partly on the temperature of the further cooling stage fluid.

47. A ColdNest according to claim 1, wherein the further cooling phase is configured to receive a corresponding control signal, including a corresponding one provided from the control system, containing information about whether to provide the further cooling stage fluid, including to the heat exchanger or the cooling reservoir for providing to the condenser in the electrical generation system, or to provide the further cooling stage fluid for subsequent further cooling, based at least partly on the temperature of the further cooling stage fluid.
